(19) United States
(12) Patent Application Publication
(10) Pub. No.: US 2016/0103156 A1
(43) Pub. Date: Apr. 14, 2016

(54) SYSTEM AND METHOD FOR MEASURING LOAD IMPEDANCE

(71) Applicant: SAVITECH CORP., Zhubei City (TW)

(72) Inventors: Hung-Chang TSAO, Zhubei City (TW); Chia-Chi CHANG, Zhubei City (TW); Shin-Chang PAN, Zhubei City (TW); Hung-Chi CHIAUNG, Zhubei City (TW); Nan-Shiung HUANG, Zhubei City (TW); Chi-Chien CHEN, Zhubei City (TW)

(73) Assignee: SAVITECH CORP., Zhubei City (TW)

(21) Appl. No.: 14/511,045

(22) Filed: Oct. 9, 2014

(51) Int. Cl. G01R 17/02; H04R 29/00

(52) U.S. Cl. CPC G01R 17/02; H04R 29/001

(57) ABSTRACT

According to one embodiment of a system for measuring a load impedance, comprising: a switch module, a first reference impedance, a second reference impedance, and a control module, wherein the switch module connects the first reference impedance, the second reference impedance, and the load impedance, respectively; the control module connects the switch module; the control module connects the first reference impedance via controlling the switch module to obtain a first voltage value; the control module connects the second reference impedance via controlling the switch module to obtain a second voltage value; the control module connects the load impedance via controlling the switch module to obtain a load voltage value; and the control module calculates the measured value of the load impedance according to the first voltage value, the second voltage value, and the load voltage value.

### TECHNICAL FIELD

The technical field generally relates to a system and method for measuring load impedance.

### BACKGROUND

With the advancement of technology, the evolution of PC and network, and the development of digital audio signal processing, the digital audio players have been used widely in various electronic systems such as audio speakers in cinemas, home, and car, and digital television, computers, music players, and mobile phones. Wherein the functionality of audio signal driving must feature with of low noise and high-quality, to make sound effect more complete. Furthermore, for fully converting the audio signal to the load impedance (i.e., speakers or headphones), the audio signal driving system may measure the load impedance, in order to adjust sound parameters to optimize the effectiveness of hearing.

FIG. 1a and FIG. 1b illustrate general architectures for measuring load impedance. FIG. 1a is a load impedance measurement technique. Refer to FIG. 1a, a current source 11 supplies a constant current I to a load impedance R. The voltage value Vout of the load impedance R is measured, then the value of the load impedance R can be obtained through the measured voltage value Vout divided by the constant current I. Another technique for measuring load impedance is shown in FIG. 1b. FIG. 1b illustrates a bridge circuit constructed by four impedances R1, R2, R3 and R4, a voltage source (not shown) supplies voltage V_{B} between the connection point of R3 and R4 and the connection point of R1 and R2. In FIG. 1b, R1 is the load impedance to be measured, R2 and R3 are impedances of specific values, and R4 is adjustable impedance. This technique adjusts the impedance R4 until the voltage difference (Vo) between the connection point of R1 and R4 and the connection point of R2 and R3 is measured zero, then the load impedance R1 can be obtained by R1=R4*R2/R3.

In the technique for measuring load impedance in FIG. 1a, the constant current I needed to be accurately measured, in order to obtain the value of the load impedance R. In the technique for measuring load impedance in FIG. 1b, after the voltage difference (Vo) is measured zero, and an accurate measurement of the adjustable impedance R4 is accomplished, then finally the value of the load impedance R1 can be obtained. These techniques for measuring load impedance are extremely complex.

Therefore, in order to improve the above shortcomings of complex impedance measurement technique with assuring constant current value or adjusting impedance value, the disclosure provides a technology for measuring load impedance.

### SUMMARY

The exemplary embodiments of the disclosure may provide system and method for measuring load impedance.

One exemplary embodiment relates to a system for measuring load impedance, applied to a load impedance, the system comprising: a switch module, a first reference impedance, a second reference impedance, and a control module, wherein the switch module connects the first reference impedance, the second reference impedance, and the load impedance, respectively; the control module connects the switch module; the control module connects the first reference impedance via controlling the switch module to obtain a first voltage value; the control module connects the second reference impedance via controlling the switch module to obtain a second voltage value; the control module connects the load impedance via controlling the switch module to obtain a load voltage value; and the control module calculates the measured value of the load impedance according to the first voltage value, the second voltage value, and the load voltage value.

Another exemplary embodiment relates to a method for measuring load impedance, applied to a load impedance, the method comprising: using a control module connects a first reference impedance via controlling a switch module to obtain a first voltage value; using the control module connects a second reference impedance via controlling the switch module to obtain a second voltage value; using the control module connects the load impedance via controlling the switch module to obtain a load voltage value; and the control module calculates the measured value of the load impedance according to the first voltage value, the second voltage value, and the load voltage value.

The foregoing will become better understood from a careful reading of a detailed description provided herein below with appropriate reference to the accompanying drawings.

### BRIEF DESCRIPTION OF THE DRAWINGS

The embodiments can be understood in more detail by reading the subsequent detailed description in conjunction with the examples and references made to the accompanying drawings, wherein:

FIG. 1a and FIG. 1b illustrate general architectures for measuring load impedance;

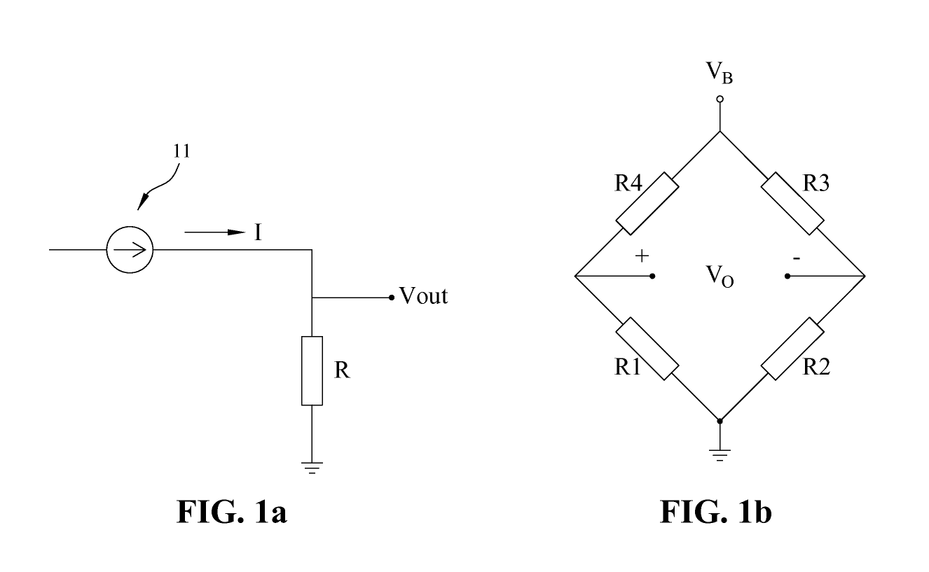

FIG. 2 illustrates a system for measuring load impedance, according to an exemplary embodiment;

FIG. 3 illustrates the circuit structure of the switch module in FIG. 2, according to an exemplary embodiment;

FIG. 4 illustrates the control module in FIG. 2 obtain the first voltage value, the second voltage value, and the load voltage via controlling the switch module, according to an exemplary embodiment;

FIG. 5 illustrates the timings of providing constant current and measuring each voltage value in FIG. 4, according to an exemplary embodiment;

FIG. 6 illustrates the control module calculates the measured value of the load impedance, according to an exemplary embodiment;

FIG. 7 illustrates a method for measuring load impedance, according to an exemplary embodiment.

### DETAILED DESCRIPTION OF THE DISCLOSED EMBODIMENTS

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

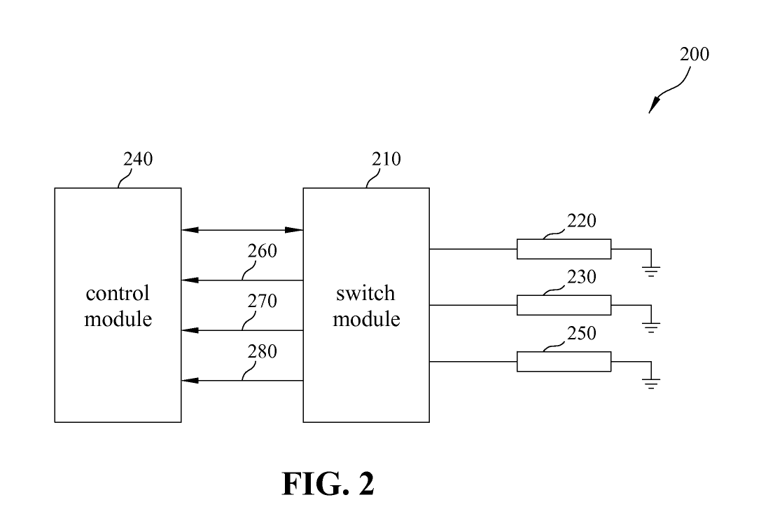

The exemplary embodiments in the disclosure may provide a technology for measuring load impedance. FIG. 2 illustrates a system for measuring load impedance, according to an exemplary embodiment. As shown in FIG. 2, the system for measuring load impedance is applied to a load impedance, and the system 200 includes a switch module 210, a first reference impedance 220, a second reference impedance 230, and a control module 240. The switch module 210 connects the first reference impedance 220, the second reference impedance 230, and the load impedance 250, respectively. The control module 240 connects the switch module 210; the control module 240 connects the first reference impedance 220 via controlling the switch module 210 to obtain a first voltage value 260; the control module 240 connects the second reference impedance 230 via controlling the switch module 210 to obtain a second voltage value 270; the control module 240 connects the load impedance 250 via controlling the switch module 210 to obtain a load voltage value 280; and the control module calculates the measured value of the load impedance according to the first voltage value 260, the second voltage value 270, and the load voltage value 280.

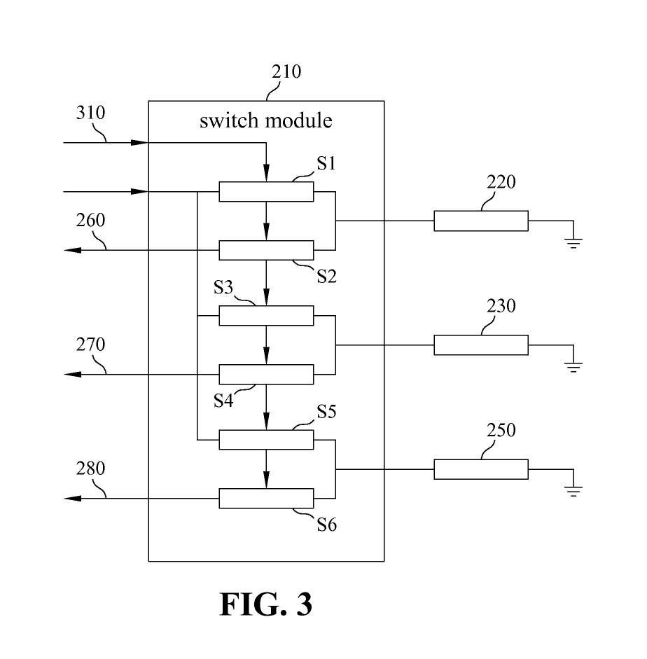

According to the exemplary embodiment in FIG. 2, the switching module 210 connects the first reference impedance 220, the second reference impedance 230, and the load impedance 250, respectively. FIG. 3 illustrates the circuit structure of the switch module 210 in FIG. 2, according to an exemplary embodiment. As shown in FIG. 3, the circuit architecture of the switching module 210 may for example, consist of six switchers S1, S2, S3, S4, S5 and S6, wherein the switchers S1 and S2 are used for connecting the first reference impedance 220, the switchers S3 and S4 are used for connecting the second reference impedance 230, and switchers S5 and S6 are used for connecting the load impedance 250. The on or off, i.e., opened (disconnected) or shorted (connected) of these six switchers are controlled by the control module 240 via a control signal 310, as shown in FIG. 3.

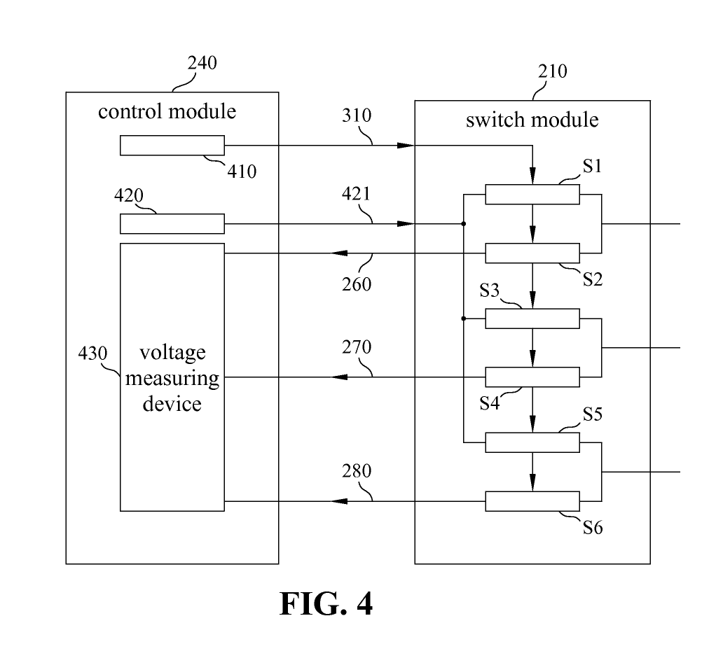

Following the above, in the exemplary embodiment of the system for measuring load impedance of FIG. 2, the control module 240 controls the switches S1 and S2, S3 and S4, and S5 and S6 via the control signal 310, in order to connect the first reference impedance 220, the second reference impedance 230, and the load impedance 250 to obtain the first voltage value 260, the second voltage value 270 and the load voltage value 280, respectively. FIG. 4 illustrates the control module 240 in FIG. 2 obtain the first voltage value 260, the second voltage value 270, and the load voltage 280 via controlling the switch module 210, according to an exemplary embodiment. As shown in FIG. 4, the control module 240 comprises a control signal generator 410, a fixed current source 420, and a voltage measuring device 430.

Refer to FIG. 4, the fixed current source 420 may produce a constant current source 421, and apply the constant current source to the first reference impedance 220, the second reference impedance 230, and the load impedance 250, respectively. The voltage measuring device 430 may measure the generated voltage value by applying the constant current source 421 to the first reference impedance 220, the second reference impedance 230, and the load impedance 250, respectively. And the control signal generator 410 may generate a control signal 310 to control disconnection or connection of the switchers S1˜S6 in the switch module 210. For example, the control signal 310 may control the switcher S1 to make the constant current source 420 providing the constant current 421 to the first reference impedance 220, and control the switcher S2 to cause the voltage measuring device 430 measure the voltage of the first reference impedance 220, i.e., the first voltage value 260. Control signal 310 may control the switcher S3 to make the constant current source 420 providing the constant current 421 to the second reference impedance 230, and control the switcher S4 to cause the voltage measuring device 430 measure the second reference impedance voltage 230, i.e., the second voltage value 270. Finally, the control signal 310 may control the switcher S5 to make the constant current source 420 providing the constant current 421 to the load impedance 250, and control the switcher S6 to cause the voltage measuring device 430 measure the voltage of the load impedance 250, i.e., the load voltage value 280.

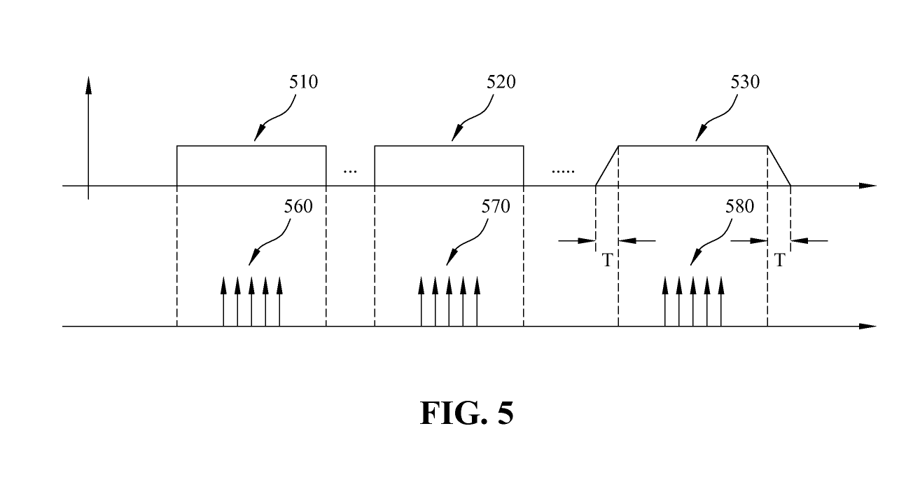

Following the above, the timing for measuring each voltage value of the voltage measuring device 430 in the control module of FIG. 4 may be coupled to the timing sequence of constant current source 420 providing the constant current 421. FIG. 5 illustrates the timings of providing constant current and measuring each voltage value in FIG. 4, according to an exemplary embodiment. As shown in FIG. 5, the signal 510 represents waveform for the constant current source 420 providing the constant current 421 to the first reference impedance 220; the signal 520 represents waveform for the constant current source 420 providing the constant current 421 to the second reference impedance 230; the signal 530 represents waveform for the constant current source 420 providing the constant current 421 to the load impedance 250, wherein the signal waveform 530 having a period of time T for rising phase and falling phase, wherein T, for example, is a period of time between 100 milliseconds (ms) and 300 milliseconds (ms) for avoiding unpleasant sonic boom on the load impedance generated by the constant current 421. In FIG. 5, the signal 560 represents the waveform of measured voltage value of the first reference impedance 220, wherein each arrow at the signal 560 indicates sampling time point for each measured voltage value of the first reference impedance 220; the signal 570 represents the waveform of measured voltage value of the second reference impedance 230, wherein each arrow at the signal 570 indicates sampling time point for each measured voltage value of the second reference impedance 230; the signal 580 represents the waveform of measured voltage value of the load impedance 250, wherein each arrow at the signal 580 indicates sampling time point for each measured voltage value of the load impedance 250. The plurality of measured voltage values of the first reference impedance at the plurality of sampling time points may then be performed statistical average to become the first voltage value; the plurality of measured voltage values of the second reference impedance at the plurality of sampling time points may then be performed statistical average to become the second voltage value; plurality of measured voltage values of the load impedance at the plurality of sampling time points may then be performed statistical average to become the load voltage value.

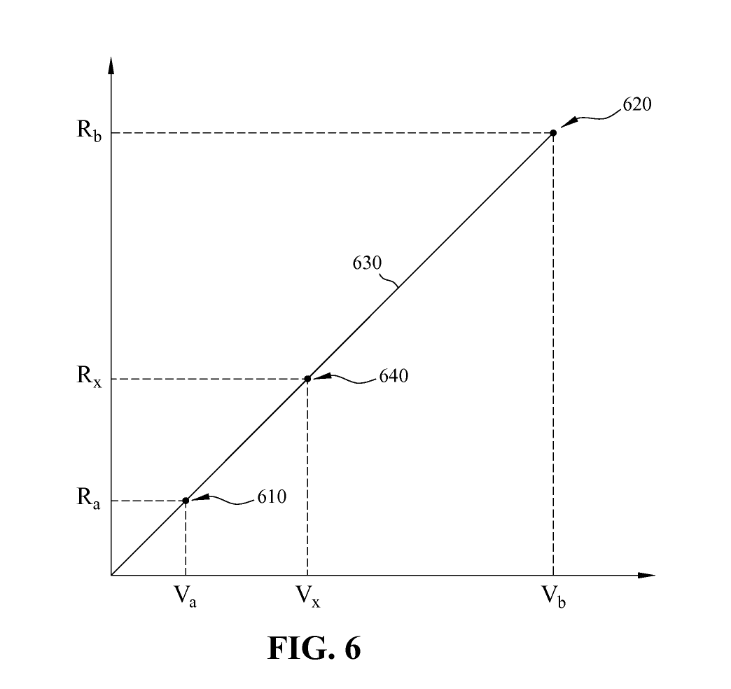

Following the above, the control module may calculate the measured value of the load impedance according to the first voltage value, the second voltage value, and the load voltage value. FIG. 6 illustrates the control module calculates the measured value of the load impedance, according to an exemplary embodiment. Refer to FIG. 6, assumed that the first reference impedance is Ra, the second reference impedance is Rb, and the load impedance is Rx; and the first voltage value, the second voltage value, and the load voltage value measured by control module are Va, Vb, and Vx, respectively. Then the load impedance Rx may be obtained with a graphical way on FIG. 6. In FIG. 6, the vertical axis represents impedance value, the horizontal axis represents voltage value. Firstly the intersection point 610 of first reference impedance Ra and the first voltage value Va is marked, then the intersection point 620 of the second reference impedance Rb and the second voltage value Vb is marked. A straight line 630 may be established between the intersection point 610 and the intersection point 620. Then the intersection point 640 on the straight line 630 may be found through the load voltage value Vx, and therefore the load impedance Rx may be obtained on the vertical axis.

As mentioned above, FIG. 6 is a graphical way to obtain the measured value of the load impedance Rx. Another way uses linear ratio to calculate the measured value of the load impedance Rx. For example, uses the following formula:

Rx=Ra+(Rb−Ra)(Vx−Va)/(Vb−Va).

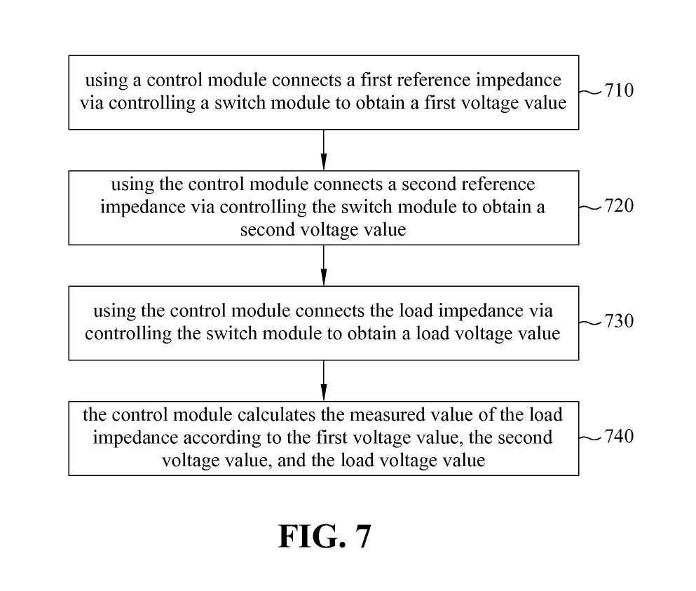

According to another exemplary embodiment, FIG. 7 illustrates a method for measuring load impedance, the method is applied to a load impedance, the method comprising: using a control module connects a first reference impedance via controlling a switch module to obtain a first voltage value (step 710); using the control module connects a second reference impedance via controlling the switch module to obtain a second voltage value (step 720); using the control module connects the load impedance via controlling the switch module to obtain a load voltage value (step 730); and the control module calculates the measured value of the load impedance according to the first voltage value, the second voltage value, and the load voltage value (step 740).

As described above, the switch module used in FIG. 7 may such as include six switchers. The control module may use a control signal to control the switch module. And the control module may apply a constant current to the first reference impedance, the second reference impedance, and the load impedance, respectively, and use a voltage measurement to obtain the first voltage value, the second voltage value, and the load voltage value, respectively. In FIG. 7, the measured value of the load impedance may be calculated based on graphical way or linear ratio.

In summary, the exemplary embodiment of the disclosure provides a system and method for measuring load impedance, so that the audio signal driving system may measure the load impedance value, in order to adjust the sound parameters to optimize the effectiveness of hearing.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A system for measuring load impedance, applied to a load impedance, the system comprising:
a switch module, connects a first reference impedance, a second reference impedance, and said load impedance, respectively; and
a control module, connects said switch module;
wherein said control module connects said first reference impedance via controlling said switch module to obtain a first voltage value; said control module connects the second reference impedance via controlling said switch module to obtain a second voltage value; said control module connects said load impedance via controlling said switch module to obtain a load voltage value; and said control module calculates measured value of said load impedance according to said first voltage value, said second voltage value, and said load voltage value.

2. The system as claimed in claim 1, wherein said switch module includes six switchers.

3. The system as claimed in claim 1, wherein said control module includes a control signal generator for generating a control signal to control said switch module.

4. The system as claimed in claim 1, wherein said control module includes a constant current source, wherein said constant current source applies a constant current to said first reference impedance, said second reference impedance, and said load impedance, respectively.

5. The system as claimed in claim 1, wherein said control module includes a voltage measuring device, wherein said voltage measuring device obtain said first voltage value, said second voltage value, and said load voltage value, respectively.

6. The system as claimed in claim 1, wherein said control module uses graphical way or linear ratio to calculate measured value of said load impedance.

7. A method for measuring load impedance, applied to a load impedance, the method comprising:
using a control module connects a first reference impedance via controlling a switch module to obtain a first voltage value;
using said control module connects a second reference impedance via controlling said switch module to obtain a second voltage value;
using said control module connects said load impedance via controlling said switch module to obtain a load voltage value; and
said control module calculates measured value of said load impedance according to said first voltage value, said second voltage value, and said load voltage value.

8. The method as claimed in claim 7, wherein said switch module includes six switchers.

9. The method as claimed in claim 7, wherein said control module uses a control signal to control said switch module.

10. The method as claimed in claim 7, wherein said control module applies a constant current to said first reference impedance, said second reference impedance, and said load impedance, respectively.

11. The method as claimed in claim 7, wherein said control module uses a voltage measurement to obtain said first voltage value, said second voltage value, and said load voltage value, respectively.

12. The method as claimed in claim 7, wherein said control module uses graphical way or linear ratio to calculate measured value of said load impedance.
